(19) United States
(12) Patent Application Publication
(10) Pub. No.: US 2019/0162810 A1
(43) Pub. Date: May 30, 2019

(54) MONITORING SYSTEM AND MONITORING METHOD

(71) Applicant: INSTITUTE FOR INFORMATION INDUSTRY, Taipei (TW)

(72) Inventors: Yi-Hsin WU, New Taipei City (TW); Cheng-Juei YU, New Taipei City (TW); Min-Cheng SHENG, Kaohsiung City (TW)

(21) Appl. No.: 15/832,763

(22) Filed: Dec. 5, 2017

(30) Foreign Application Priority Data
Nov. 30, 2017 (TW) 106141944

(51) Int. Cl. G01R 35/00

(52) U.S. Cl. CPC G01R 35/005

(57) ABSTRACT

A monitoring system includes a first storage device and a processor. The first storage is configured to temporarily store a first iterated value corresponding to first history parameters. The processor is configured to receive first parameters of first products tested by a test machine, generate a second iterated value by performing an iterative calculation of the first parameters and the first iterated value, and update the first iterated value temporarily stored in the first storage device to the second iterated value for follow-up iterative calculations to selectively output an alert information, wherein the second iterated value corresponds to the first parameters and the first history parameters.

### CROSS-REFERENCE TO RELATED APPLICATION

This application claims priority to Taiwan Application Ser. No. 106141944, filed on Nov. 30, 2017, which is herein incorporated by reference.

### BACKGROUND

### Field of Invention

The present invention relates to a monitoring system and a monitoring method. More particularly, the present invention relates to a monitoring system and a monitoring method for monitoring a test result of products tested by a test machine.

### Description of Related Art

In order to ensure functions of products, the products will be tested by a test machine before being shipped. Taking IC package for an example, an electrical performance test of the IC package will be executed before the IC package is shipped.

However, in conventional test mechanism, when components of a test machine are unstable or have a breakdown, the test machine would perform a misjudgment that available products are determined as faulty products. Therefore, when there are too many faulty products, test programs would be paused and the components have to be fixed, which results in ineffective consumptions of labor power and delay of product delivery time. Besides, because of reference data/reference value for comparing and testing is stored in a hard disk drive (HDD), a solid state disk (SSD) or redundant array of independent disks (RAID), a processor for comparing and testing must access data from above storage devices to compare and test. However, the number of data are too many in above storage devices, so it is hard for the conventional test mechanism to compare and test tested-data/tested-value with the reference data/reference value, and provide corresponding suggestions.

### SUMMARY

The invention provides a monitoring system and a monitoring method.

The monitoring system includes a first storage device and a processor. The first storage is configured to temporarily store a first iterated value corresponding to first history parameters. The processor is configured to receive first parameters of first products tested by a test machine, the processor is configured to generate a second iterated value by performing an iterative calculation of the first parameters and the first iterated value, and to update the first iterated value temporarily stored in the first storage device 110 to the second iterated value to for follow-up iterative calculations, to selectively output an alert information, wherein the second iterated value corresponds to the first parameters and the first history parameters.

The monitoring method applies to a monitoring system, and the monitoring system includes a first storage device and a processor. The monitoring method includes a step of receiving, by the processor, first parameters of first products tested by a test machine, a step of generating, by the processor, a second iterated value by performing an iterative calculation of the first parameters and the first iterated value, wherein the first iterated value corresponds to the first history parameters, and a step of updating, by the processor, the first iterated value temporarily stored in the first storage device 110 to the second iterated value for follow-up iterative calculations to selectively output an alert information by the processor, wherein the second iterated value corresponds to the first parameters and the first history parameters.

### BRIEF DESCRIPTION OF THE DRAWINGS

In order to more clearly illustrate the above and other object, features, advantages and embodiments of the present disclosure, the accompany drawings are as follows.

FIG. 1A is a block diagram of a monitoring system for testing first products in accordance with an embodiment of the present disclosure;

FIG. 1B is a block diagram of a processor of the monitoring system for testing the first products in accordance with an embodiment of the present disclosure;

FIG. 2 is a flow chart of a monitoring method in accordance with an embodiment of the present disclosure;

FIG. 3A is a block diagram of the monitoring system for testing second products in accordance with an embodiment of the present disclosure;

FIG. 3B is a block diagram of the processor of the monitoring system for testing the second products in accordance with an embodiment of the present disclosure;

FIG. 4 is a flow chart of a monitoring method in accordance with an embodiment of the present disclosure;

FIG. 5 is a block diagram of the monitoring system for testing fourth products in accordance with an embodiment of the present disclosure;

FIG. 6 is a flow chart of a monitoring method in accordance with an embodiment of the present disclosure;

FIG. 7A is a block diagram of the monitoring system for testing fifth products in accordance with an embodiment of the present disclosure;

FIG. 7B is a block diagram of the processor of the monitoring system for testing the fifth products in accordance with an embodiment of the present disclosure; and

FIG. 8 is a flow chart of a monitoring method in accordance with an embodiment of the present disclosure.

### DETAILED DESCRIPTION

The following is cited embodiments accompanied with figures are described in detail, but the examples are not provided to limit the scope of the invention covered by the non-operation of the structure described in order to limit its implementation, any by the structure regrouping of the components, the device has equal efficacy to produce, it is all covered by the scope of the present invention.

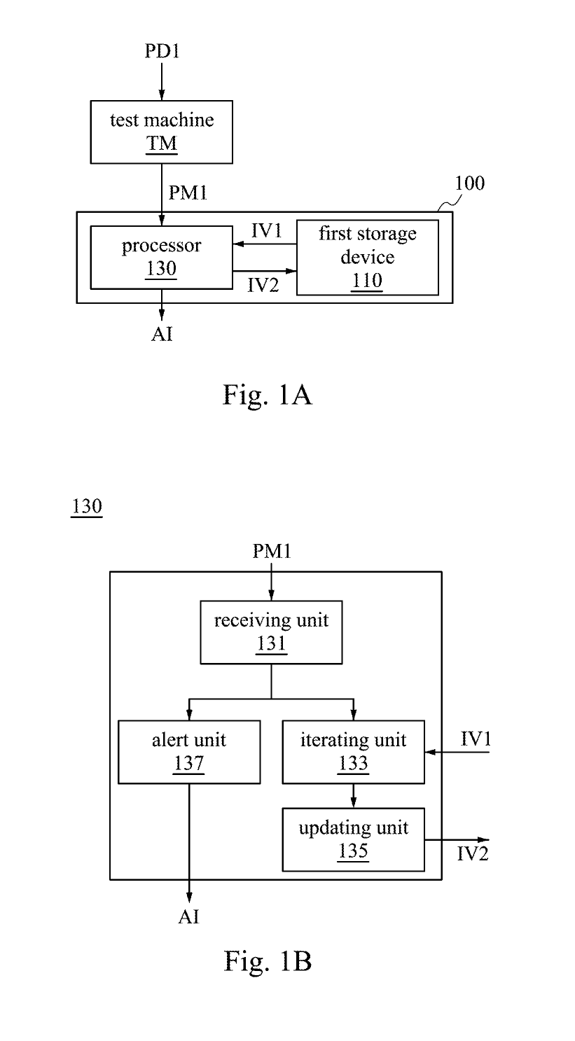

Referring to FIG. 1A and FIG. 1B. FIG. 1A is a block diagram of a monitoring system 100 for testing first products PD1 in accordance with an embodiment of the present disclosure. FIG. 1B is a block diagram of a processor 130 of the monitoring system 100 for testing the first products PD1 in accordance with an embodiment of the present disclosure.

The monitoring system 100 includes a first storage device 110 and a processor 130, wherein the processor 130 may include a receiving unit 131, an iterating unit 133, an updating unit 135 and an alert unit 137.

The monitoring system 100 may communicate with a test machine TM by wired communication (e.g., a cable, an optical fiber or a waveguide) or wireless communication (e.g., Wi-Fi, Bluetooth, 2G, 3G, 4G), and the monitoring system 100 is configured to monitor a test result of products tested by the test machine TM, and then provide corresponding suggestions according to the test result. For example, if the test result of the products indicates that the products have low yield rate (wherein reasons of low yield rate are that the products have a breakdown or components of the test machine TM have a breakdown), the monitoring system 100 provides corresponding suggestions according to low yield rate, such as a suggestion of switching off partial components, a suggestion of pausing the test, or a suggestion of remaining the test.

In an embodiment, the first storage device 110 may be a register, but the first storage device 110 in this disclosure is not limited thereto, and devices that temporarily store data are within a scope of this disclosure. The processor 130 may be a micro controller, a microprocessor, a digital signal processor, an application specific integrated circuit (ASIC) or a logic circuit, but the processor 130 in this disclosure is not limited thereto, and devices that process signals are within a scope of this disclosure.

The first storage device 110 is configured to temporarily store a first iterated value VI1 corresponding first history parameters, wherein the first history parameters and the first iterated value IV1 are known.

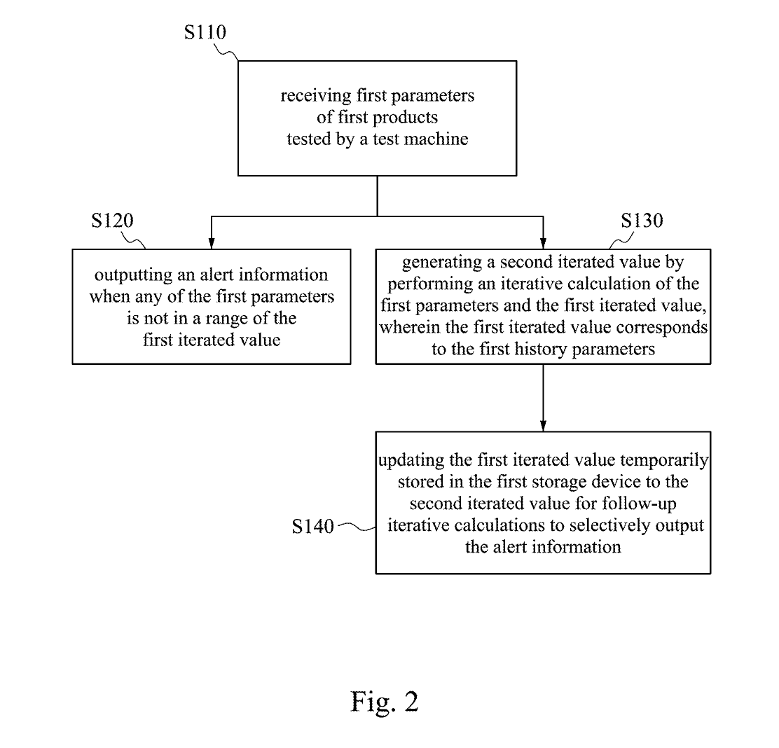

Referring FIG. 1A, FIG. 1B and FIG. 2. FIG. 2 is a flow chart of a monitoring method in accordance with an embodiment of the present disclosure. The monitoring method shown in FIG. 2 may be executed by the processor 130 of the monitoring system 100 shown in FIG. 1A and FIG. 1B.

In step S110, the receiving unit 131 of the processor 130 is configured to receive the first parameters PM1 of the first products PD1 tested by the test machine TM.

In step S120, the alert unit 137 of the processor 130 is configured to output an alert information AI when any of the first parameters PM1 is not in a range of the first iterated value IV1.

In step S130, the iterated unit 133 of the processor 130 is configured to generate a second iterated value IV2 by performing an iterative calculation of the first parameters PM1 and the first iterated value IV1, wherein the iterative calculation is performed when the processor 130 is configured to group parameters with same value in the first parameters PM1 and the first history parameters corresponding to the first iterated value IV1 into groups through data binning technique, and the groups include a first group and a second group. The number of parameters included in the first group is greater than the number of parameters included in the second group, and the second iterated value IV2 is calculated by the processor 130 based on the number and values of the parameters included in the first group and according to the number and values of the parameters included in the second group. It should be noted that the iterative calculation is example, but the iterative calculation in this disclosure is not limited thereto.

In step S140, the updating unit 135 of the processor 130 is configured to update the first iterated value IV1 temporarily stored in the first storage device 110 to the second iterated value IV2 for follow-up iterative calculations to selectively output the alert information AI, wherein the second iterated value IV2 corresponds to the first parameters PM1 and the first history parameters.

In the following terms, the application of the monitoring system 100 will be describe, and taking an example to describe that the monitoring system 100 applies to a domain of monitoring package test for IC design. It should be noted that the domain is example, but the domain in this disclosure is not limited thereto.

In the example, the test machine TM may be a test machine for testing IC package, wherein the test machine TM may include test components for testing IC package, such as a socket configured to carry the IC package, a test probe configured to perform an electric performance test and a robotic arm configured to grab and move the IC package. Then, a test item is taken an input voltage test as an example.

The first products may be IC package.

The first parameters PM1 may be a test value corresponded the test item as an example. Because the test item is the input voltage test, the test value is an input voltage.

Then, the monitoring system 100 is configured to monitor an operation mechanism of the first products PD1 under the input voltage test.

The first storage device 110 is configured to temporarily store the first iterated value IV1 corresponding to the first history parameters. For example, there are five data in the first history parameter, and the five data are 9V, 10V, 10V, 10V and 10V. Then, parameters with same value in above five data of the first history parameters will be group into two groups. The two groups are a group formed from 10V and a group formed from 9V. The number of the first history parameters are four in the group formed from 10V. The number of the first history parameters are one in the group formed from 9V. Therefore, the number of the first history parameters in the group formed from 10V are the most. Then, based on the number (i.e., four) and values (i.e., 10V) of the parameters in the group formed from 10V, the first iterated value IV1 is determined according to the number (i.e., one) and values (i.e., 9V) of the parameters in the group formed from 9V. Specifically, because the number of 10V is four and the number of 9v is one, the first iterated value IV1 is from 9V to 10V and near 10V, e.g., 9.8V. It should be noted that the first iterated value IV1 is example, but the first iterated value IV1 in this disclosure is not limited thereto.

The receiving unit 131 of the processor 130 is configured to receive the first parameters PM1 of the first products PD1 tested by the test machine TM, wherein the number of the first products PD1 is taken 5 as an example, and input voltage levels of the first products PD1 are 9V, 10V, 10V, 10V and 10V. As a result, the first parameters PM1 are 9V, 10V, 10V, 10V and 10V, respectively.

The iterated unit 133 of the processor 130 is configured to group the parameters with same value in the first parameters PM1 (i.e., 9V, 9V, 10V, 10V and 10V) and the first history parameters (i.e., 9V, 10V, 10V, 10V and 10V), wherein the number of the parameters with 10V are seven, and the parameters with 10V form a first group; and the number of the parameters with 9V are three, and the parameters with 9V form a second group. The number of the parameters included in the first group is greater than the number of the parameters included in the second group.

Then, the second iterated value IV2 is calculated based on the number (i.e., seven) and the value (i.e., 10V) of the parameters in the first group and according to the number (i.e., three) and the value (i.e., 9V) of the parameters in the second group. Specifically, because the number of 10V are seven and the number of 9V are three, the second iterated value IV2 is from 9V to 10V and near 10V, e.g., 9.7V. It should be noted that the second iterated value IV2 is example, but the second iterated value IV2 in this disclosure is not limited thereto.

The alert unit 137 of the processor 130 is configured to determine that if any of the parameters PM1 is not in the range defined as a range of the first iterated value IV1, e.g., 9.8±1V. Therefore, the range is 8.8V˜10.8V. If any of the first parameters PM1 is not in the range, e.g., 8V, it means the input voltage level of the corresponding first product PD1 is abnormal. As a result, the alert unit 137 outputs the alert information Al to notify the person in charge.

In other embodiment, the range is defined as 9.8V±(standard deviation).

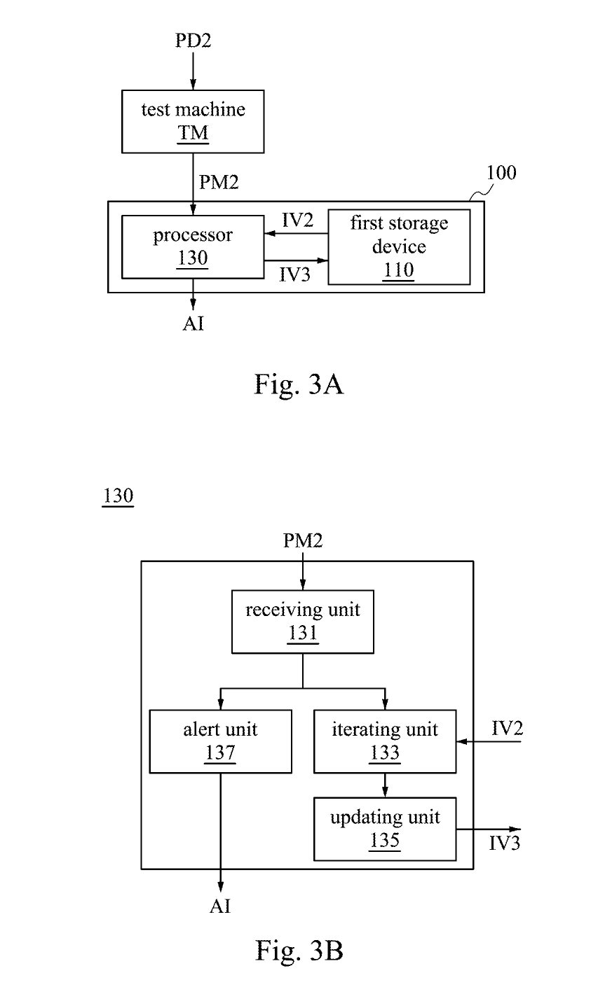

Referring to FIG. 3A and FIG. 3B. FIG. 3A is a block diagram of the monitoring system 100 for testing second products PD2 in accordance with an embodiment of the present disclosure. FIG. 3B is a block diagram of the processor 130 of the monitoring system 100 for testing the second products PD2 in accordance with an embodiment of the present disclosure.

The monitoring system 100 is configured to test the second products PD2 that are the same as the first products PD1 after the first products PD1 was tested.

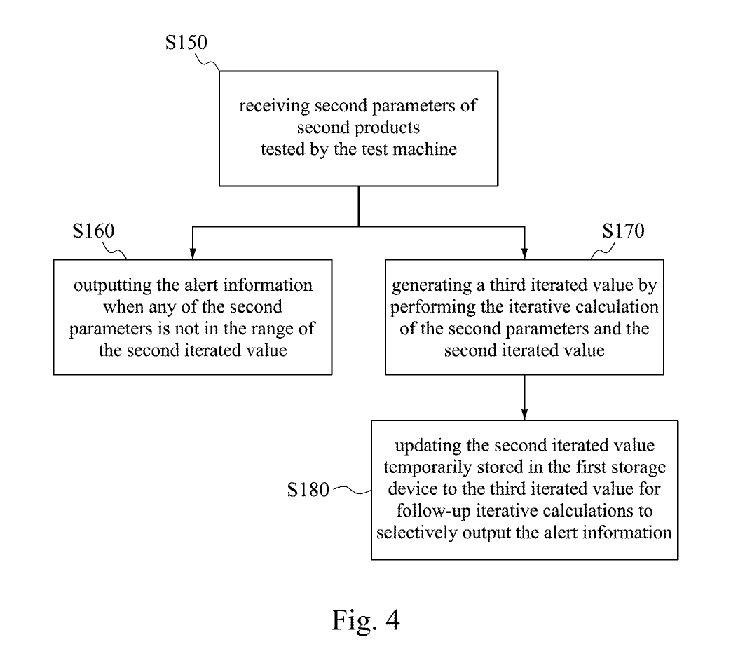

A test mechanism of the second products PD2 is almost similar to a test mechanism of the first products PD1, but there are some differences between them. Therefore, in the following terms, the test mechanism of the second products PD2 will be described with FIG. 3A, FIG. 3B and FIG. 4. FIG. 4 is a flow chart of a monitoring method in accordance with an embodiment of the present disclosure. The monitoring method shown in FIG. 4 may be executed by the processor 130 of the monitoring system 100 shown in FIG. 3A and FIG. 3B, and steps of the monitoring method shown in FIG. 4 are executed after the step S140 of the monitoring method shown in FIG. 4.

In step S150, the receiving unit 131 of the processor 130 is configured to receive second parameters PM2 of the second products PD2 tested by the test machine TM.

In step S160, the alert unit 137 of the processor 130 is configured to output the alert information AI when any of the second parameters PM2 is not in the range of the second iterated value IV2.

In step S170, the iterated unit 133 of the processor 130 is configured to generate a third iterated value IV3 by performing the iterative calculation of the second parameters PM2 and the second iterated value IV2, wherein the iterative calculation is performed when the processor 130 is configured to group parameters with same value in the second parameters PM2, the first parameters PM1 and the first history parameters into groups through data binning technique, and the groups include a first group and a second group, the number of parameters included in the first group is greater than the number of parameters included in the second group, the third iterated value IV3 is calculated by the processor 130 based on the number and values of the parameters included in the first group and according to the number and values of the parameters included in the second group. It should be noted that the iterative calculation is example, but the iterative calculation in this disclosure is not limited thereto.

In step S180, the updating unit 135 of the processor 130 is configured to update the second iterated value IV2 temporarily stored in the first storage device 110 to the third iterated value IV3 for follow-up iterative calculations to selectively output the alert information

Then, the monitoring system 100 is configured to monitor an operation mechanism of the second products PD2 under the input voltage test.

The first storage device 110 is configured to temporarily store the second iterated value IV2 corresponding to the first parameters PM1 and the first history parameters.

The receiving unit 131 of the processor 130 is configured to receive the second parameters PM2 of the second products PD2 tested by the test machine TM, wherein the number of the second products PD2 is taken 5 as an example, and input voltage levels of the second products PD2 are 9V, 9V, 9V, 9V and 10V. As a result, the second parameters PM2 are 9V, 9V, 9V, 9V and 10V, respectively.

The iterated unit 133 of the processor 130 is configured to group the parameters with same value in the second parameters PM2 (i.e., 9V, 9V, 9V, 9V and 10V), the first parameters PM1 (i.e., 9V, 9V, 10V, 10V and 10V) and the first history parameters (i.e., 9V, 10V, 10V, 10V and 10V), wherein the number of the parameters with 10V are eight, and the parameters with 10V form a first group; and the number of the parameters with 9V are seven, and the parameters with 9V form a second group. The number of the parameters included in the first group is greater than the number of the parameters included in the second group.

Then, the third iterated value IV3 is calculated based on the number (i.e., eight) and the value (i.e., 10V) of the parameters in the first group and according to the number (i.e., seven) and the value (i.e., 9V) of the parameters in the second group. Specifically, because the number of 10V are eight and the number of 9V are seven, the third iterated value IV3 is from 9V to 10V and near 10V, e.g., 9.6V. It should be noted that the third iterated value IV3 is example, but the third iterated value IV3 in this disclosure is not limited thereto.

The alert unit 137 of the processor 130 is configured to output the alert information AI when any of the second parameters PM2 is not in the range defined as a range of the second iterated value IV2. The determination mechanism of the second parameters PM2 is the same as the determination mechanism of the first parameters PM1, so the determination mechanism of the second parameters PM2 is not necessary to repeat in detail.

According to the above, the range determined by the alert information AI will vary with different values (e.g., the first iterated value IV1, the second iterated value VI2 and the third iterated value IV3) temporarily stored in the first storage device 110. That is, the range of abnormal values determined by the alert unit 137 of the processor 130 will vary with result of the iterative calculation every time. As a result, it could determine that the components of the test machine TM are abnormal or the products are abnormal, then corresponding suggestions will be provide.

Furthermore, within the determination made by the alert unit 137 of the processor 130, used data is accessed from the first storage device 110, so the calculating speed will be increased to achieve a purpose of alerting immediately.

Therefore, when products tested this time and products tested last time by the test machine TM are the same, parameters of the products tested this time and parameters of the products tested last time are made the iterative calculation to calculate an appropriate normal range adaptively. As a result, accuracy and benefit of product testing will be increased.

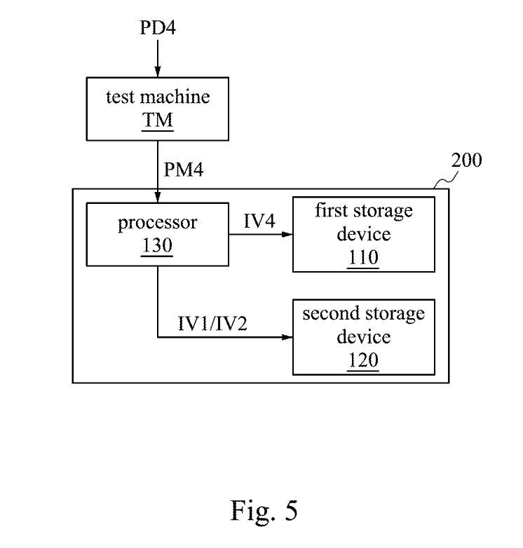

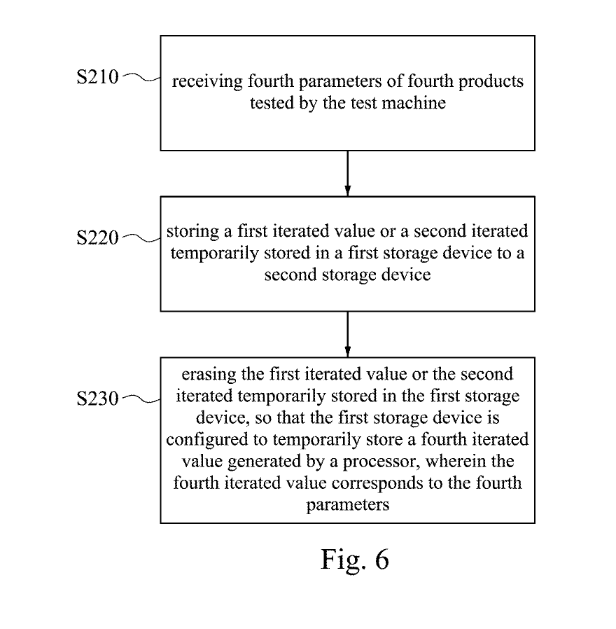

Referring to FIG. 5 and FIG. 6. FIG. 5 is a block diagram of the monitoring system 200 for testing fourth products PD4 in accordance with an embodiment of the present disclosure. FIG. 6 is a flow chart of a monitoring method in accordance with an embodiment of the present disclosure;

The monitoring system 100 is configured to test the fourth products PD4 that are the different from the second products PD2 after the second products PD2 was tested.

The monitoring system 200 shown in FIG. 5 is almost similar to the monitoring system 100 shown in FIG. 1A, a difference is that the monitoring system 200 further includes a second storage device 120, and other same components are not necessary to repeat in detail.

In an embodiment, the second storage device 120 may be a hard disk drive (HDD), a solid state disk (SSD) or redundant array of independent disks (RAID). However, the second storage device 120 in this disclosure is not limited thereto, and devices that store data are within a scope of this disclosure.

In step S210, a receiving unit (not shown) of the processor 130 is configured to receive the fourth parameters PM4 of the forth products PD4 tested by the test machine TM.

In step S220, a moving unit (not shown) of the processor 130 is configured to store the second iterated value IV2 temporarily stored in the first storage device 110 into the second storage device 120.

In step S230, a erasing unit (not shown) of the processor 130 is configured to erase the second iterated value IV2 temporarily stored in the first storage device 110, and the first storage device 110 is configured to temporarily store fourth iterated value IV4 generated by the processor 130, wherein the fourth iterated value IV4 corresponds to the fourth parameters PM4.

Then, the monitoring system 200 is configured to monitor an operation mechanism of the fourth products PD4 under the input voltage test.

The first storage device 110 is configured to temporarily store the fourth iterated value IV4 corresponding to the fourth parameters PM4. For example, there are five data in the fourth parameters PM4, and the five data are 9V, 10V, 10V, 10V and 10V. Then, parameters with same value in above five data of the fourth parameters PM4 will be group into two groups. The two groups are a group formed from 10V and a group formed from 9V. The number of the fourth parameters PM4 are four in the group formed from 10V. The number of the fourth parameters PM4 are one in the group formed from 9V. Therefore, the number of the fourth parameters PM4 in the group formed from 10V are the most. Then, based on the number (i.e., four) and values (i.e., 10V) of the parameters in the group formed from 10V, the four iterated value IV4 is determined according to the number (i.e., one) and values (i.e., 9V) of the parameters in the group formed from 9V. Specifically, because the number of 10V is four and the number of 9v is one, the fourth iterated value IV4 is from 9V to 10V and near 10V, e.g., 9.8V. It should be noted that the first iterated value IV1 is example, but the fourth iterated value IV4 in this disclosure is not limited thereto.

The processor 130 is configured to store the second iterated value IV2 temporarily stored in the first storage device 110 into the second storage device 120. That is, 9.7V defined above is stored in the second storage device 120.

The processor 130 is configured to erase the second iterated value IV2 temporarily stored in the first storage device 110, and the first storage device 110 is configured to temporarily store the fourth iterated value IV4 generated by the processor 130, wherein the fourth iterated value IV4 corresponds to the fourth parameters PM4.

Therefore, when products tested this time and products tested last time by the test machine TM are different, the steps S210 to S230 will be execute.

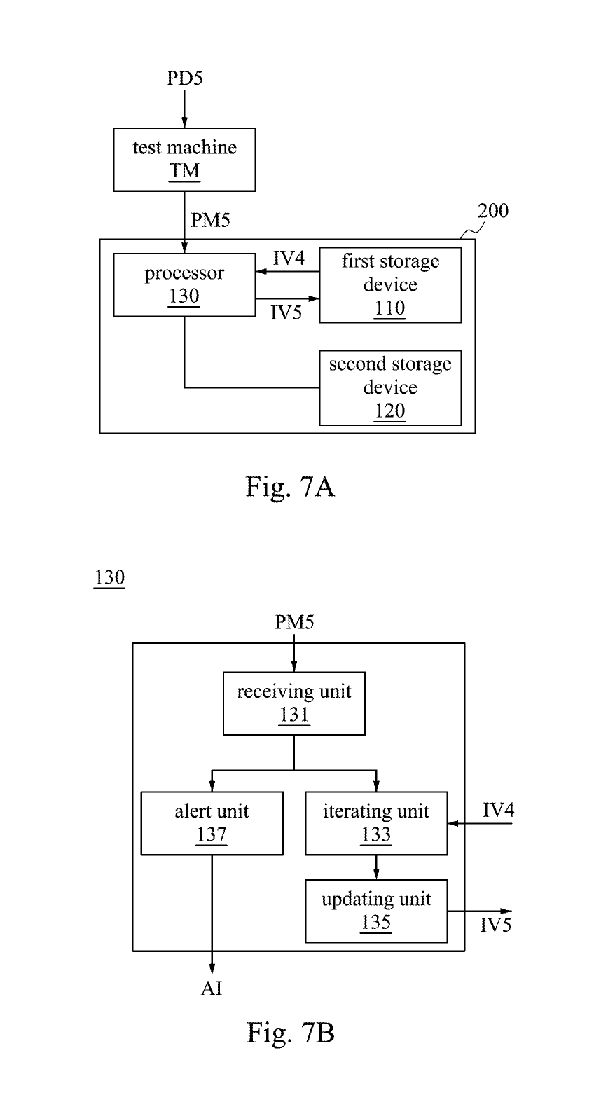

Referring to FIG. 7A and FIG. 7B. FIG. 7A is a block diagram of the monitoring system 200 for testing fifth products PD5 in accordance with an embodiment of the present disclosure. FIG. 7B is a block diagram of the processor 130 of the monitoring system 200 for testing the fifth products PD5 in accordance with an embodiment of the present disclosure.

The monitoring system 200 is configured to test the fifth products PD5 that are the same as the fourth products PD4 after the fourth products PD4 was tested.

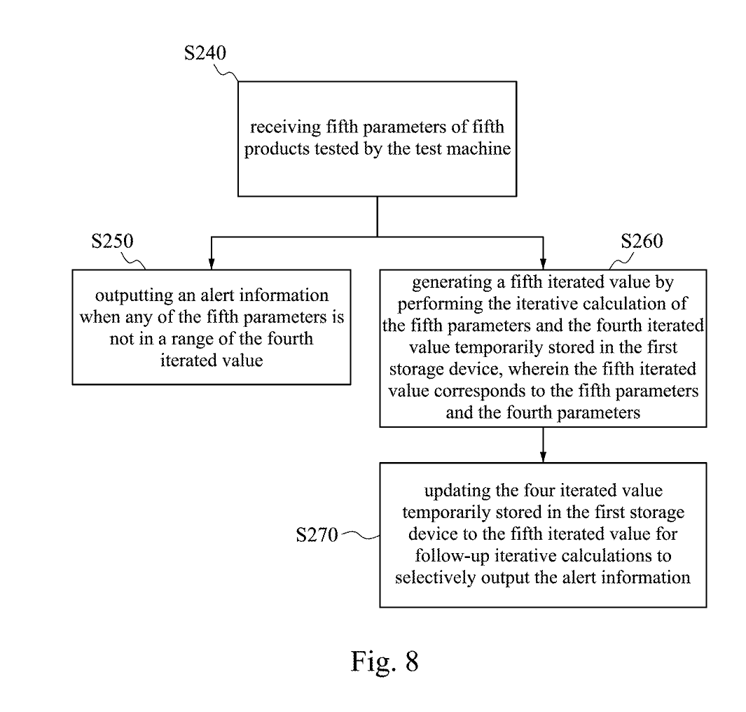

A test mechanism of the fifth products PD5 is almost similar to the test mechanism of the first products PD1, but there are some differences between them. Therefore, in the following terms, the test mechanism of the fifth products PD5 will be described with FIG. 7A, FIG. 7B and FIG. 8. FIG. 8 is a flow chart of a monitoring method in accordance with an embodiment of the present disclosure. The monitoring method shown in FIG. 8 may be executed by the processor 130 of the monitoring system 200 shown in FIG. 7A and FIG. 7B, and steps of the monitoring method shown in FIG. 8 are executed after the step S230 of the monitoring method shown in FIG. 6.

In step S240, the receiving unit 131 of the processor 130 is configured to receive the fifth parameters PM5 of the fifth products PD5 tested by the test machine TM.

In step S250, the alert unit 137 of the processor 130 is configured to output the alert information AI when any of the fifth parameters PM5 is not in the range of the fourth iterated value IV4.

In step S260, the iterated unit 133 of the processor 130 is configured to generate a fifth iterated value IV5 by performing the iterative calculation of the fifth parameters PM5 and the fourth iterated value IV4, wherein the fifth iterated value IV5 corresponds to the fifth parameters PM5 and the fourth parameters PM4. The iterative calculation in the step S260 is the same as the iterative calculation in the step S130, so the iterative calculation is not necessary to repeat in detail.

In step S270, the updating unit 135 of the processor 130 is configured to update the fourth iterated value IV4 temporarily stored in the first storage device 110 to the fifth iterated value IV5 for follow-up iterative calculations to selectively output the alert information.

Because a test mechanism of the fifth products PD5 is almost similar to the test mechanism of the first products PD1 and the second products PD2, so the test mechanism of the fifth products PD5 is not necessary to repeat in detail.

In summary, the monitoring system and the monitoring method of the present disclosure are configured to use the first storage device and the processor with the iterative calculation to increase the accuracy and benefit of the product testing, and achieve the purpose of alerting immediately.

Although the case has been described above in Example revealed, however it is not intended to limit the present case, any skilled in the art, without departing from the spirit and scope of the case, when available for a variety of modifications and variations, and therefore the case Depending on the scope of protection of the rights after the appended claims and their equivalents.

What is claimed is:

1. A monitoring system, comprising:
a first storage device configured to temporarily store a first iterated value corresponding to first history parameters; and
a processor configured to receive first parameters of first products tested by a test machine, the processor configured to generate a second iterated value by performing an iterative calculation of the first parameters and the first iterated value, and to update the first iterated value temporarily stored in the first storage device to the second iterated value for follow-up iterative calculations, to selectively output an alert information, wherein the second iterated value corresponds to the first parameters and the first history parameters.

2. The monitoring system of claim 1, wherein the iterative calculation is performed when the processor is configured to group parameters with same value in the first parameters and the first history parameters corresponding to the first iterated value, into groups, and the groups include a first group and a second group, the number of parameters included in the first group is greater than the number of parameters included in the second group, and the processor is configured, based on the number and values of the parameters included in the first group, to determine the second iterated value according to the number and values of the parameters included in the second group.

3. The monitoring system of claim 1, wherein the processor is configured to output the alert information when any of the first parameters is not in a range of the first iterated value.

4. The monitoring system of claim 1, wherein when the test machine tests second products, the processor is configured to receive second parameters of the second products, generate a third iterated value by performing the iterative calculation of the second parameters and the second iterated value, and update the second iterated value temporarily stored in the first storage device to the third iterated value, wherein the third iterated value corresponds to the first parameters, the first history parameters and the second parameters, and the processor is configured to selectively output the alert information according to the second iterated value.

5. The monitoring system of claim 4, wherein the processor is configured to output the alert information when any of the second parameters is not in a range of the first iterated value.

6. The monitoring system of claim 1, further comprising:
a second storage device, wherein the processor is configured to store, in the second storage device, the first iterated value or the second iterated value temporarily stored in the first storage device, and erase the first iterated value or the second iterated temporarily stored in the first storage device, so that the first storage device is configured to temporarily store other iterated values generated by the processor.

7. A monitoring method applied to a monitoring system, the monitoring system comprises a first storage device and a processor, wherein the monitoring method comprises:
receiving, by the processor, first parameters of first products tested by a test machine;
generating, by the processor, a second iterated value by performing an iterative calculation of the first parameters and the first iterated value, wherein the first iterated value corresponds to the first history parameters; and
updating, by the processor, the first iterated value temporarily stored in the first storage device to the second iterated value for follow-up iterative calculations, to selectively output an alert information, wherein the second iterated value corresponds to the first parameters and the first history parameters.

8. The monitoring method of claim 7, wherein the iterative calculation is performed when the processor is configured to group parameters with same value in the first parameters and the first history parameters corresponding to the first iterated value into groups, and the groups include a first group and a second group, the number of parameters included in the first group is greater than the number of parameters included in the second group, and the processor is configured, based on the number and values of the parameters included in the first group, to determine the second iterated value according to the number and values of the parameters included in the second group.

9. The monitoring method of claim 7, wherein after a step of receiving, by the processor, the first parameters of the first products tested by the test machine by the processor, further comprising:
outputing, by the processor, the alert information when any of the first parameters is not in a range of the first iterated value.

10. The monitoring method of claim 7, wherein after a step of updating, by the processor, the first iterated value temporarily stored in the first storage device to the second iterated value for follow-up iterative calculations to selectively output the alert information, further comprising:
receiving, by the processor, second parameters of second products tested by the test machine;
generating, by the processor, a third iterated value by performing the iterative calculation of the second parameters and the second iterated value; and
updating, by the processor, the second iterated value temporarily stored in the first storage device to the third iterated value for follow-up iterative calculations to selectively output the alert information.

11. The monitoring method of claim 10, wherein after a step of receiving, by the processor, the second parameters of the second products tested by the test machine, further comprising:
outputting, by the processor, the alert information when any of the second parameters is not in a range of the second iterated value.

12. The monitoring method of claim 7, wherein after a step of updating, by the processor, the first iterated value temporarily stored in the first storage device to the second iterated value for follow-up iterative calculations to selectively output the alert information, further comprising:
storing, by the processor, the first iterated value or the second iterated value temporarily stored in the first storage device in a second storage device; and
erasing, by the processor, the first iterated value or the second iterated temporarily stored in the first storage device, so that the first storage device is configured to temporarily store other iterated values.
